(19) United States
(12) Patent Application Publication
(10) Pub. No.: US 2014/0159749 A1
(43) Pub. Date: Jun. 12, 2014

(54) AUTOMATIC FAUCET SENSOR AND ATTACHMENT FOR THE SAME

(71) Applicant: MASCO CORPORATION, Taylor, MI (US)

(72) Inventors: Jeffrey John Belz, Sterling Heights, MI (US); Paul McLennan, London (CA)

(73) Assignee: MASCO CORPORATION, Taylor, MI (US)

(21) Appl. No.: 13/708,950

(22) Filed: Dec. 8, 2012

(51) Int. Cl. G01R 27/26

(52) U.S. Cl. CPC G01R 27/2605
USPC 324/690

(57) ABSTRACT

A sensor module for a position sensor includes a circuit board with a capacitance sensor and a tool clip probe mechanically connected to the circuit board and electrically connected to the circuit board. The tool clip probe is a capacitive sensor probe and a mechanical support for the sensor module.

### BACKGROUND

The present disclosure is related generally to position sensing devices, and more specifically to a position sensing device for an automatic plumbing fixture.

Position sensing automated devices, such as automatic faucets or drinking fountains, utilize position sensors built into the structure of the faucet to determine the position of a user relative to the metal fixture of the faucet. When the user is closer than a certain distance, the faucet activates and begins dispensing water. Similar arrangements are also utilized in drinking fountains, showers, flushometers, or other plumbing fixtures.

A common type of position sensing device used in these arrangements is a capacitive based sensor. The capacitive based sensor detects a capacitance between the metal fixture of the faucet and the person approaching or leaving the fixture. The strength of the capacitance varies depending on the distance between the person and the fixture according to known principles. In this way, a capacitance probe contacting the fixture can sense the capacitance and a controller can utilize the sensed capacitance to determine the position of the person.

### SUMMARY

Disclosed is a sensor module for a position sensor including a circuit board having a capacitance sensor and a tool clip probe mechanically connected to the circuit board and electrically connected to the circuit board, such that the tool clip probe is a capacitive sensor probe and a mechanical support.

Also disclosed is a tool clip probe for a sensor module including a planar base portion and a plurality of arms extending from said planar base portion. Each of the arms further includes a hinge portion, a first bottleneck portion, a bowed portion, and a second bottleneck portion. The tool clip probe is electrically conductive.

These and other features of this application will be best understood from the following specification and drawings, the following of which is a brief description.

### BRIEF DESCRIPTION OF THE DRAWINGS

FIG. 1 schematically illustrates an automatic faucet arrangement including a position sensing device.

FIG. 2 schematically illustrates a side view of a sensor module for use in the position sensing device of FIG. 1.

FIG. 3 schematically illustrates an isometric view of the sensor module of FIG. 2.

FIG. 4 schematically illustrates an isometric view of an example tool clip probe for use in conjunction with the sensor module of FIG. 2.

FIG. 5 schematically illustrates an alternate tool clip probe that can be used in the sensor module of FIG. 2.

### DETAILED DESCRIPTION

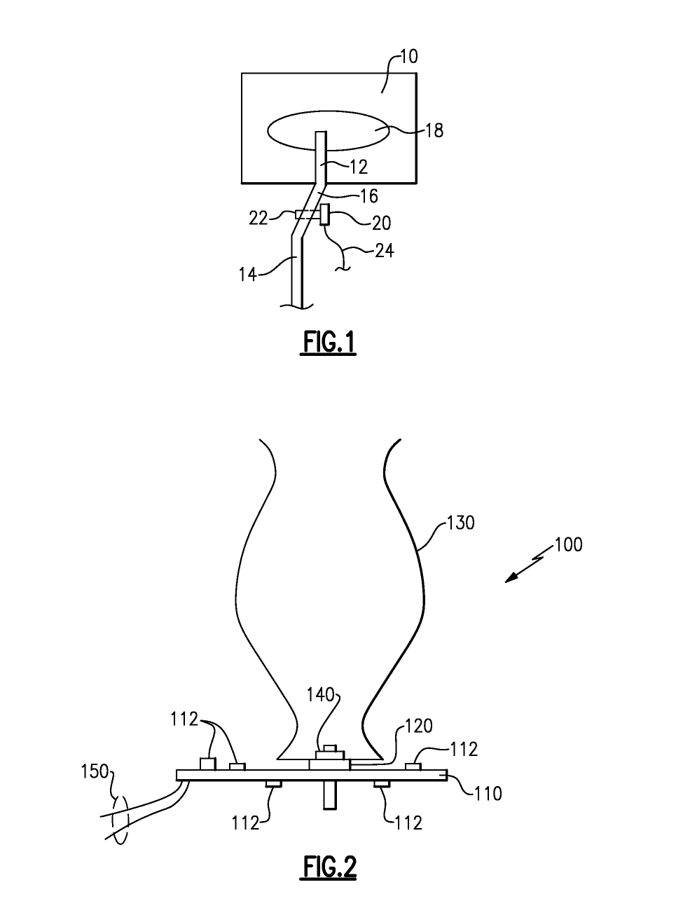

FIG. 1 illustrates an automatic faucet arrangement 10 having a faucet spout 12 and a sink 18. The faucet spout 12 is connected to a water supply pipe 14 via a standard faucet shank 16. A capacitive based position sensor module 20 for a position sensing device is connected to the faucet shank 16 via a tool clip probe 22. The sensor module 20 includes a digital output line 24 that transmits the sensed data to a controller remote from the sensor module 20 thereby facilitating position based control. The controller utilizes the data to control water flow through the water supply pipe 14, turning the faucet 12 on when a person approaches the faucet 12, and off when the person leaves the faucet 12.

Existing position sensing devices use a long sensor wire contacting a length of the faucet shank 16 to detect the capacitance between the faucet 12/faucet shank 16 arrangement and the user approaching the faucet 12/faucet shank 16 arrangement. The dielectric gap of the capacitor is the distance between the person and the faucet 12/faucet shank 16 arrangement. This sensor arrangement is referred to as a capacitive based position sensing device, and the strength of the detected capacitance corresponds to the distance between the user and the faucet 12.

The tool clip probe 22 of the illustrated sensor module 20 serves a double purpose of simultaneously mechanically holding the sensor module 20 in place, and providing an electrically conductive capacitance probe able to detect the capacitance of the faucet 12/faucet shank 16 arrangement. The tool clip probe 22 is electrically connected to a probe input of the sensor module 20, and replaces the length of sensor wire used in the prior art.

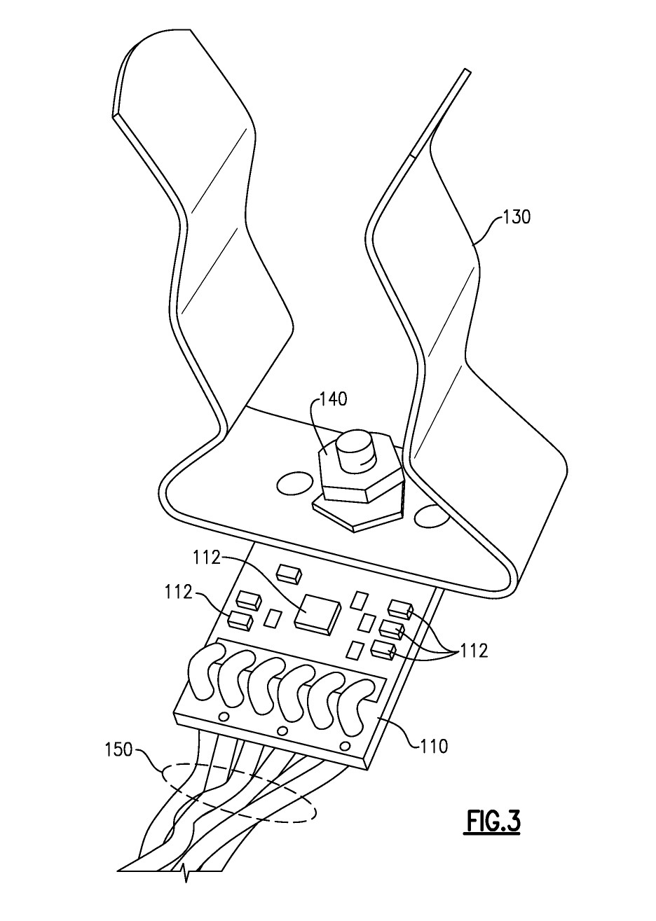

FIG. 2 illustrates a side view of a sensor module 100 for use in the example automatic faucet arrangement 10 of FIG. 1. FIG. 3 illustrates an isometric view of the sensor module 100 of FIG. 2 with like numerals indicating like elements between FIGS. 2 and 3. The sensor module 100 includes a circuit board 110. The circuit board 110 houses multiple electric components 112, including a capacitance probe input 120. Also included among the electric components 112 is a processor and a memory as well as any other elements required to process the sensed capacitance. The electric components 112 operate in conjunction with each other to interpret a sensed capacitance from the tool clip probe 130. While FIGS. 2 and 3 illustrate the sensor probe 110 without a housing protecting the on board electronics 112/120 or the connections, a practical application of the sensor probe 110 are encapsulated within a housing to protect the components from environmental conditions.

The processor component 112 converts the sensed capacitance into a distance value representing how far a user is from the faucet 12/faucet shank 16 arrangement illustrated in FIG. 1. The distance value is then converted by the processor component 112 into a digital form and output at a digital output 150. The digital output 150 is connected to a controller remote from the sensor module 20. The controller controls the faucet 12/water supply pipe 14 arrangement based on the sensed position of the user as described above.

The tool clip probe 130 is connected to the capacitance probe input 120 via a fastener 140 and provides an electrical connection between the capacitance probe input and the faucet 12/water supply pipe 14 arrangement. In the illustrated example, the fastener 140 is a conductive bolt and nut arrangement connecting the tool clip probe 130 to the capacitance probe input 120. In alternate examples, a conductive base surface of the tool clip probe 130 directly contacts the capacitance probe input 120, and the fastener 140 is non-conductive. It is further possible to use alternate fastening means to connect the tool clip probe 130 to the capacitive input 120. Another example alternate fastening means is an electrically conductive adhesive.

In place of the tool clip 130, alternate conductive fastening means can be used to connect the sensor module 100 and the capacitance probe input 120 to the faucet shank 16. Alternate potential fastening means include soldering, brazing, welding, mechanical crimping, pressfitting, constricting bands, threaded joints, or barbed clips.

By providing a conductive path between the faucet 12/water supply pipe 14 arrangement and the capacitance probe input 120, the tool clip probe 130 renders a sensor wire contacting a length of the water supply pipe 14 unnecessary. Omitting the sensor wire in turn increases the ease of installation as a workman installing the sensor is not required to align the sensor wire or ensure that the sensor wire does not inadvertently contact another metal structure within the faucet 12/water supply pipe 14 arrangement.

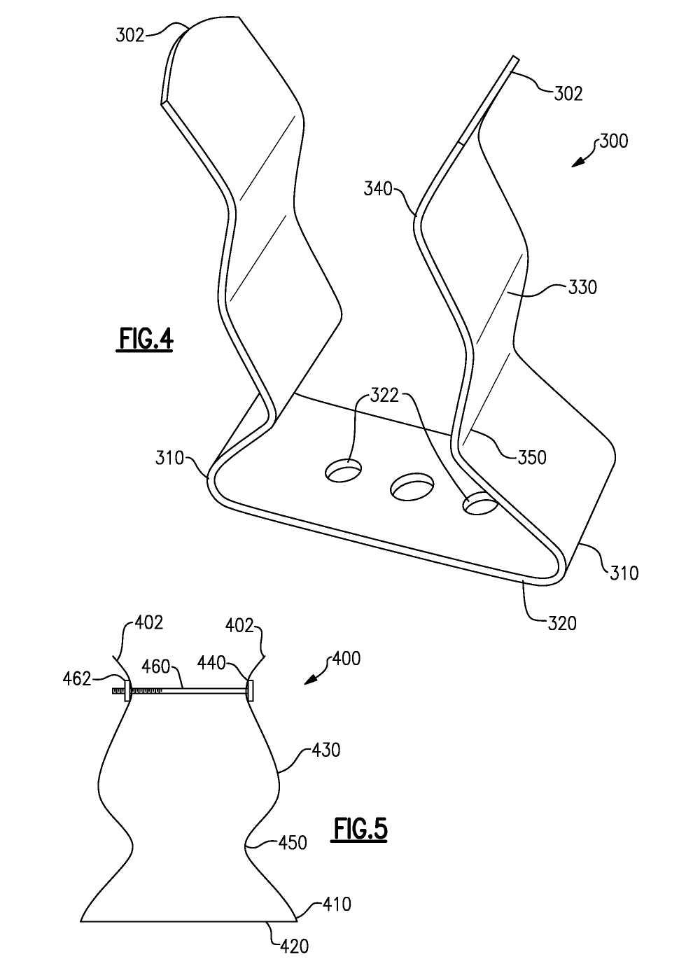

FIG. 4 illustrates an isometric view of a tool clip probe 300 for use in conjunction with a sensor module 100 (illustrated in FIGS. 2 and 3) for a position sensing device. The tool clip probe 300 has a planar base portion 320 that abuts the capacitance probe input of a sensor module (not pictured) providing the electric connection between the capacitance probe input 120 (see FIGS. 2 and 3) and the tool clip probe 300. The planar base portion 320 includes at least one fastener feature 322 for facilitating a fastener connecting the tool clip probe 300 to the capacitance probe input 120 of the circuit board within the sensor module. Connected to opposing edges of the planar base portion 320 via hinge portions 310 are a pair of tool clip probe arms 302.

Each of the hinge portions 310 bend the tool clip probe arms 302 to an angle less than 90° relative to the planar base portion 320. By angling the hinge portion 310 towards the center of the planar base portion 320 in such a manner, each arm 302 of the tool clip probe 300 pushes inwards causing the hinge portion 310 to exert force on a faucet shank positioned between the tool clip probe arms 302, thereby holding the sensor module in position. The hinge portions 310 have a range of motion that is limited to elastic deformation of the hinge portion 310. The range of motion is limited in order to prevent a permanent loss of retention force.

Each tool clip probe arm 302 includes a clamp portion 330 that is connected to the hinge portion 310 of the tool clip probe arm 302 via a bottleneck portion 350. The bottleneck portion 350 of each tool clip probe arm 302 has a shorter distance between itself and an opposing bottleneck portion than the diameter of the faucet shank that the tool clip probe 300 is connected to. The bottleneck portions 350 prevent the faucet shank from moving passed the clamp portion 330, and inadvertently contacting the planar base portion 320. The clamp portion 330 is further bowed away from the center of the planar base portion 320 to accommodate the round shape and diameter of a faucet shank. The bowed portion 330 of each tool clip probe arm 302 is bounded on a second edge of the bowed portion 330, opposite the first bottleneck portion 350, by a second bottleneck portion 340. The second bottleneck portion 340 functions similar to the first bottleneck portion 350, however, the second bottleneck portion 340 allows the faucet shank to pass when a threshold amount of pressure is exerted on the tool clip probe 330. In this way, the faucet shank can be positioned in the bowed portion 330 between the first and second bottleneck portions 340, 350 of each tool clip probe arm 302. The spring pressure of the tool clip 130 allows strain relief of a sensor head when engaged to prevent damage to the signal cable 24 due to a high tensile force. The tool clip 130 releases from the shank 16 before damage occurs to the cable or PCB.

FIG. 5 illustrates a second example tool clip probe 400 similar to the first example tool clip probe 300 illustrated in FIG. 4. As with the tool clip probe 300 of FIG. 4, the illustrated tool clip probe 400 of FIG. 5 includes a planar base portion 420, a hinge portion 410, a first and second bottleneck portion 440, 450 and a clamp portion 430. Unlike the example of FIG. 4, the hinge portion 410 does not exert enough force on the faucet shank through the bowed clamp portion 430, to maintain the sensor module in position connected to the faucet shank. To increase the clamping force exerted by the bowed portion on the faucet shank, a tightening bar 460 is connected to the second bottleneck portion 440 of each tool clip probe arms 402. Thus an affect of the tightening bar 460 is to increase spring pressure and/or electrical conductivity of the tool clip probe 130.

In the example of FIG. 5, the tightening bar 460 is a threaded or partially threaded bolt and nut 462 arrangement. The tightening bar 460 prevents inadvertent movement or shifting of sensor assembly on the faucet shank 16. The bar 460 also prevents tampering, vandalism or theft when installed in public spaces. Alternatively, a fully threaded bar including a nut 462 on each end can be utilized to the same effect. When installing the tool clip probe 400 of FIG. 5, the faucet shank is placed between the bowed portions 430 of each tool clip probe arm 402. The sensor module is maintained in place by the installer, and the tightening bar 460 is passed through a hole in each tool clip probe arm 402. Once in place, the nut 462 of the tightening bar 460 is placed on the end tightening bar 460. The nut 462 is then tightened until the bowed portions 430 fully clamp the faucet shank such that the sensor module is maintained in place without the assistance of the installer. Alternatively, other types of tightening bars 460 can be utilized to the same effect.

The above disclosure is described with regards to a faucet and sink arrangement including a position sensing device. However, it is understood that the above disclosure can be applied to any similar systems such as an automatic drinking fountain, or any automatic plumbing fixture, including a position sensor device with only minor modifications to the disclosed design. It is further understood, that similar shaped tool clip probes could be utilized to achieve the same function and still fall within the above described disclosure.

Although examples of this invention have been disclosed, a worker of ordinary skill in this art would recognize that certain modifications would come within the scope of this invention. For that reason, the following claims should be studied to determine the true scope and content of this invention.

1. A sensor module for a position sensor comprising:
a circuit board including a capacitance sensor;
a tool clip probe protruding from said circuit board, wherein said tool clip probe is mechanically connected to said circuit board and electrically connected to said circuit board, such that said tool clip probe is a capacitive sensor probe and a mechanical support.

2. The sensor module of claim 1, wherein said capacitance sensor includes a probe input.

3. The sensor module of claim 2, wherein said tool clip probe is electrically coupled to said capacitive probe input via a conductive fastener.

4. The sensor module of claim 2, wherein said tool clip probe is electrically coupled to said probe input via contact between a planar base portion of said tool clip probe and said probe input.

5. The sensor module of claim 2, wherein said circuit board further includes a processor and a memory, and wherein said memory stores instructions operable to cause said processor to convert a detected capacitance into a distance measurement.

6. The sensor module of claim 5, wherein said circuit board includes analog to digital converters operable to convert a processor output to a digital value representative of the processor output.

7. The sensor module of claim 1, wherein said circuit board comprises at least one digital output.

8. The sensor module of claim 1, wherein said tool clip probe is a conductive tool clip including a planar base portion and two arms extending away from the circuit board, wherein each of said tool clip probe arms is connected to said planar base portion via a hinge portion.

9. The sensor module of claim 8, wherein each of said hinge portions is angled toward a center of said planar base portion relative to a plane defined by said planar base portion.

10. The sensor module of claim 8, wherein each tool clip probe arm further includes a first bottleneck portion connected to the hinge portion, a bowed portion connected to the first bottleneck portion and a second bottleneck portion connected to the bowed portion and opposite the first bottleneck portion.

11. The sensor module of claim 10, further comprising a tightening rod connected said second bottleneck portion of each of said tool clip probe arms.

12. The sensor module of claim 8, wherein said planar base portion of said tool clip probe is connected to said probe input via a fastener.

13. A tool clip probe for a sensor module comprising:
a planar base portion;
a plurality of arms extending from said planar base portion, wherein each of said arms further comprises a hinge portion, a first bottleneck portion, a bowed portion, and a second bottleneck portion; and
wherein said tool clip probe is electrically conductive.

14. The tool clip probe of claim 13, wherein each of said hinge portions are angled towards a center of said planar portion.

15. The tool clip probe of claim 14, wherein each of said hinge portions is angled at less than 90 degrees relative to the planar portion.

16. The tool clip probe of claim 13, wherein each of said bowed portions are bowed away from the other of said bowed portions thereby creating a gap between each of said bowed portions.

17. The tool clip probe of claim 13, further comprising a tightening bar connecting a second bottleneck portion of each tool clip probe arm.

18. The tool clip probe of claim 13, wherein said planar base portion includes at least one fastener feature for facilitating a fastener connection.
